(19) United States
(12) Patent Application Publication
(10) Pub. No.: US 2026/0182358 A1
(43) Pub. Date: Jun. 25, 2026

(54) ETCH STOP LAYER ISOLATION FROM METAL VIAS AND CONTACTS

(71) Applicant: Taiwan Semiconductor Manufacturing Company, Ltd., Hsin-Chu (TW)

(72) Inventors: Rui-Fu Chen, Hsinchu City (TW); Hsin Yang Hung, New Taipei City (TW); Shih-Jung Ho, Hsinchu City (TW); Kuan-Kan Hu, Hsinchu (TW); Wei-Xiang You, Kaohsiung City (TW)

(21) Appl. No.: 19/190,151

(22) Filed: Apr. 25, 2025

Related U.S. Application Data
(60) Provisional application No. 63/738,588, filed on Dec. 24, 2024.

(51) Int. Cl. H01L 23/532; H01L 21/768; H01L 23/522; H01L 23/528; H10D 30/00; H10D 30/01; H10D 30/43; H10D 62/10; H10D 84/01; H10D 84/83

(52) U.S. Cl. CPC H10W 20/47; H10D 30/014; H10D 30/019; H10D 30/43; H10D 30/502; H10D 62/121; H10D 84/0149; H10D 84/832; H10W 20/072; H10W 20/075; H10W 20/076; H10W 20/095; H10W 20/42; H10W 20/435; H10W 20/46; H10W 20/495

(57) ABSTRACT

One aspect of the present disclosure pertains to a structure. The structure includes a first interlayer dielectric (ILD) layer; a conductive feature disposed in the first ILD layer; an etch stop layer (ESL) disposed on the first ILD layer; a second ILD layer disposed on the ESL; and a metal feature disposed in the second ILD layer and in contact with the conductive feature, where the metal feature is laterally separated from the ESL by an air gap.

### PRIORITY DATA

This application claims the benefit of U.S. Provisional Application No. 63/738,588, filed Dec. 24, 2024, which is hereby incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As feature sizes continue to decrease, metal vias and contacts need to fit into smaller spaces while minimizing contact resistance. Fitting metal material into smaller spaces often produce seams or voids, thereby degrading electrical connection. One way to address this is through bottom-up metal growth. However, during bottom-up metal growth, impurities in the etched-through etch stop layers (ESLs) may come into contact with deposited metal, thereby causing selective loss during the bottom-up growth. Further, portions of the ESLs that sandwich the metal contacts/vias also contribute to unwanted parasitic capacitance.

Therefore, although existing methods of forming semiconductor metal vias/contacts have been generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a flow chart of a method to form a semiconductor device having gate contacts and source/drain vias, in portion or in entirety, according to an embodiment of the present disclosure.

FIG. 2 illustrates a three-dimensional view of a semiconductor IC structure with a line A-A′ cutting across the IC structure, according to an embodiment of the present disclosure.

FIGS. 3-8 illustrate cross-sectional views of a semiconductor device cut along the line A-A′ in FIG. 2 at intermediate stages of fabrication and processed in accordance with the method of FIG. 1, according to an embodiment of the present disclosure.

FIG. 9 illustrates a flow chart of a method to form metal vias or contacts isolated from etch stop layers, in portion or in entirety, according to an embodiment of the present disclosure.

FIGS. 10A-10B illustrate different methods of forming sacrificial and protective liners as part of the method of FIG. 9.

FIGS. 11-19 illustrate cross-sectional views of a film stack at intermediate stages of fabrication and processed in accordance with the method of FIGS. 9 and 10A, according to an embodiment of the present disclosure.

FIGS. 20A-20B illustrate metal vias or contacts isolated from etch stop layers, according to further embodiments of the present disclosure.

FIGS. 21-28 illustrate cross-sectional views of a film stack at intermediate stages of fabrication and processed in accordance with the method of FIGS. 9 and 10B, according to an embodiment of the present disclosure.

FIGS. 29A-29B illustrate metal vias or contacts isolated from etch stop layers, according to further embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “under,” “below,” “lower,” “above,” “over,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Still further, when a number or a range of numbers is described with “about,” “approximate,” “substantially,” and the like, the term is intended to encompass numbers that are within a reasonable range including the number described, such as within +/−10% of the number described, or other values as understood by person skilled in the art. For example, the term “about 5 nm” may encompass the dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” or the like, may be understood to be within +/−10% between the compared features. Further, disclosed dimensions of the different features can implicitly disclose dimension ratios between the different features.

In semiconductor manufacturing, metal vias (or contacts) are formed through various interlayer dielectric (ILD) and etch stop layers (ESLs). However, direct contact between the metal vias and the ESL may impair device performance. The direct contact may induce greater parasitic coupling (especially if the ESL is a high-k dielectric such as silicon nitride (SiN)). Specifically, portions of the ESL that sandwich the metal via may contribute to unwanted capacitive coupling, which degrades overall device performance. Further, direct contact with the ESL may induce selective metal loss due to impurities in the ESL reacting with deposited metal (e.g., during metal bottom-up growth). For example, the ESL may include a low-k dielectric such as silicon carbonitride (SiCN), and the carbon impurities react with the deposited bottom-up metal, causing tapered landing on the underlying feature, reducing surface contact and degrading electrical connection. As such, there is a need to improve effective capacitance where high-k ESL is used while also preventing selective metal loss when low-k ESL is used.

For this and other reasons, the present disclosure provides a method to form metal vias (or contacts) isolated from etch stop layers (ESLs). A dummy sacrificial liner (e.g., silicon liner) and a protective liner (e.g., SiOx liner) are used to form separation between the ESL and the metal via. The sacrificial liner is selectively removed to form air walls, and the air walls are sealed by ion implantation to form air spacers (or air gaps). Meanwhile, the protective liner layer remains on sidewalls of the metal via and can be considered part of the interlayer dielectric after the airwalls are sealed. In the present embodiment, the metal vias (or contacts) are laterally spaced from the ESL by protective liner portions of the interlayer dielectric and the air spacers. The air spacers lowers the capacitance of the ESL (e.g., from 3.8 to 1 when the ESL includes SiCN), and the protective liner enables bottom-up growth without impurity. In the present embodiment, the metal vias (or contacts) are formed through bottom-up deposition to form vias (or contacts) without voids and with lowered resistance.

To illustrate the various aspects of the present disclosure, methods of forming a semiconductor device (or structure) are discussed below. Embodiments shown in the present disclosure are implemented with Gate-All-Around (GAA) field effect transistors (FETs), but the present disclosure is not limited thereto. GAA FETs refer to transistors having gate stacks (gate electrodes and gate dielectric layers) surrounding transistor channels, such as vertically-stacked gate-all-around horizontal nanowire or nanosheet MOSFET devices. Those of ordinary skill in the art should appreciate that they may readily use the present disclosure as a basis for designing or modifying other structures for carrying out the same purposes and/or achieving the same advantages of the embodiments introduced herein. For example, the embodiments herein may also be implemented with planar MOSFETs, FinFETs, Forksheet FETs, complementary FETs (CFETs), vertically stacked FETs, and/or combinations thereof.

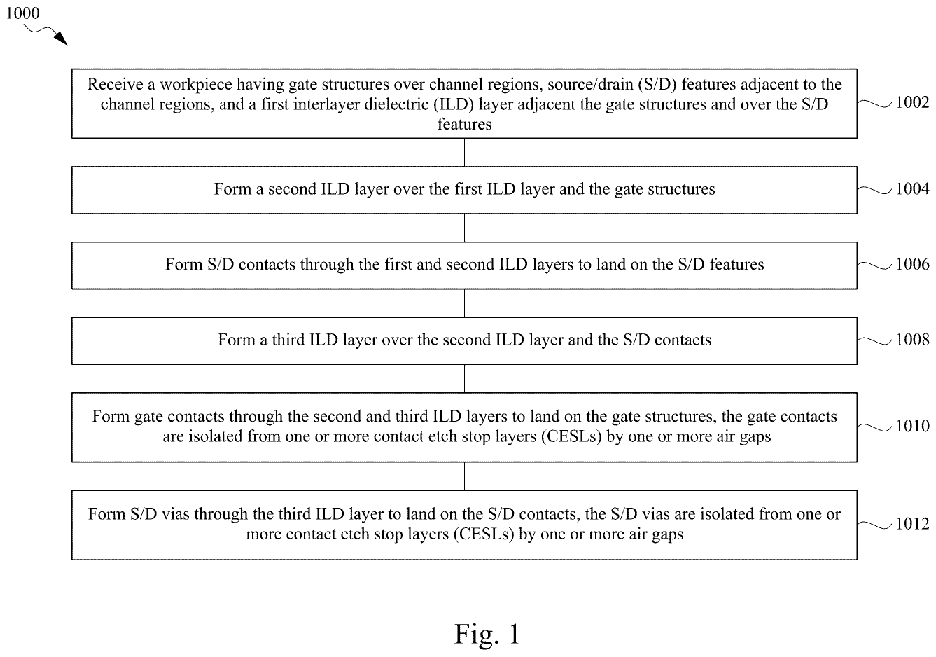

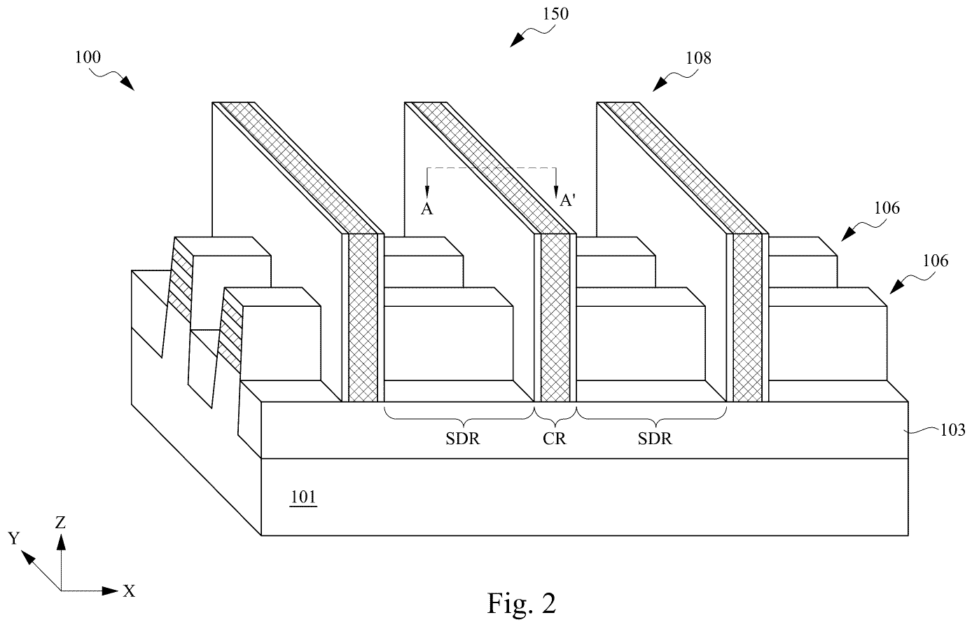

FIG. 1 illustrates a flow chart of a method 1000 to form a semiconductor device 100 having gate contacts and source/drain vias, in portion or in entirety, according to an embodiment of the present disclosure. The method 1000 is described below with reference to FIGS. 2-8. These figures have been simplified for the sake of clarity to better understand the inventive concepts of the present disclosure. Additional features can be added in the semiconductor device 100, and some of the features described below can be replaced, modified, or eliminated in other embodiments of the semiconductor device 100.

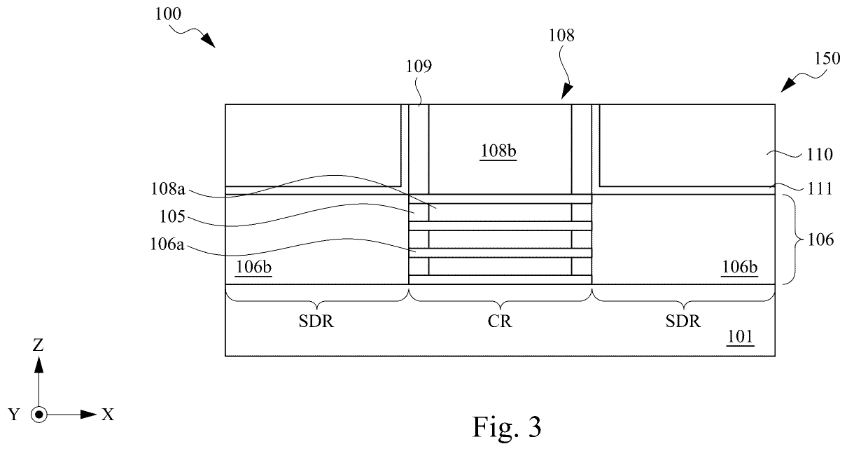

Referring to FIGS. 2-3, the method 1000 at operation 1002 receives a semiconductor IC structure 150. As detailed below, the semiconductor IC structure 150 includes gate structures 108 over channel regions CR, source/drain (S/D) features 106b adjacent to the channel regions CR (e.g., in S/D regions SDR), and a first interlayer dielectric (ILD) layer 110 adjacent the gate structures 108 and over the S/D features 106b.

FIG. 2 illustrates a three-dimensional view of the semiconductor IC structure 150. The semiconductor IC structure 150 corresponds to a semiconductor device 100 at an initial or intermediate stage of fabrication. The semiconductor device 100 may be a portion of an integrated circuit (IC) chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), complementary metal-oxide semiconductor (CMOS) transistors, bipolar junction transistors (BJTs), laterally diffused MOS (LDMOS) transistors, high voltage transistors, high frequency transistors, other suitable components, or combinations thereof. In some embodiments, the device is included in a non-volatile memory, such as a non-volatile random access memory (NVRAM), a flash memory, an electrically erasable programmable read only memory (EEPROM), an electrically programmable read-only memory (EPROM), other suitable memory type, or combinations thereof.

The semiconductor device 100 includes a substrate 101 and one or more semiconductor stacks 106 protruding from the substrate 101 above an isolation structure 103. The isolation structure 103 is disposed over the substrate 101 and provides isolation between adjacent semiconductor stacks 106 and may be a shallow trench isolation (STI) layer. In an example process, a dielectric material for the isolation structure 103 is deposited over the IC structure 150 using CVD, subatmospheric CVD (SACVD), flowable CVD, physical vapor deposition (PVD), spin-on coating, and/or other suitable process. Then the deposited dielectric material is planarized and recessed until the semiconductor stacks 106 rises above the isolation structure 103. The dielectric material for the isolation structure 103 may include silicon oxide, silicon oxynitride, fluorine-doped silicate glass (FSG), a low-k dielectric, combinations thereof, and/or other suitable materials.

The semiconductor device 100 further includes one or more gate structures 108 (or gate stacks) disposed over channel regions CR of the semiconductor stacks 106. The semiconductor stacks 106 may also be referred to as semiconductor fins 106 or fin active regions 106. The semiconductor stacks 106 extend lengthwise along the X direction, and the gate structures 108 extend lengthwise along the Y direction. As shown, the semiconductor stacks 106 include channel regions CR between source/drain regions SDR. The channel regions CR refer to regions of the semiconductor stacks 106 directly below and wrapped around by the gate structure 108.

FIG. 2 illustrates a line A-A′ that cuts along a semiconductor stack 106 in the X direction (lengthwise direction of the semiconductor stacks 106). The line A-A′ cuts across two source/drain regions SDR and a channel region CR between the two source/drain regions SDR. FIGS. 3-8 illustrate cross-sectional views of the semiconductor IC structure 150 cut along the line A-A′ and processed in accordance with the method 1000 of FIG. 1.

FIG. 3 illustrates additional details of the initial IC structure 150. As shown, the channel regions CR may include vertically stacked channels 106a, the S/D regions SDR may include S/D epitaxial features 106b, and the channels 106a laterally extend between the S/D epitaxial features 106b along the X direction. The S/D epitaxial features 106b may include n-type S/D features that correspond with n-type GAA transistor regions or p-type source/drain features that correspond with p-type GAA transistor regions. The S/D epitaxial features 106b may be formed by an epitaxy process using CVD deposition techniques (for example, VPE and/or UHV-CVD), molecular beam epitaxy, other suitable epitaxial growth processes, or combinations thereof. The S/D epitaxial features 106b are doped with n-type dopants and/or p-type dopants. In some embodiments, for the n-type GAA transistors, S/D epitaxial features 106b include silicon and can be doped with carbon, phosphorous, arsenic, other n-type dopant, or combinations thereof (for example, forming Si:C epitaxial source/drain features, Si:P epitaxial source/drain features, or Si:C:P epitaxial source/drain features). In some embodiments, for the p-type GAA transistors, S/D epitaxial features 106b include silicon germanium or germanium and can be doped with boron, other p-type dopant, or combinations thereof (for example, forming Si:Ge:B epitaxial source/drain features).

Still referring to FIG. 3, the gate structures 108 engages and wraps around each of the channels 106a. The gate structures 108 include a gate dielectric layer (not explicitly shown) and a gate electrode (not explicitly shown) disposed on the gate dielectric layer. In some embodiments, the gate dielectric layer includes an interfacial layer and a high-k dielectric layer disposed on the interfacial layer. The gate electrode may include one or more conductive materials, such as a capping layer, a work function metal layer, a blocking layer, a metal fill layer, and/or other proper conductive material layers. The work function layers (if present) may be same or different and may be an n-type work function layer or a p-type work function layer, depending on the types of the corresponding GAA transistors. The gate dielectric layer includes a high-k dielectric material, such as materials having a dielectric constant greater than silicon oxide (k≈3.9). The metal fill layer includes a suitable conductive material, such as Al, W, and/or Cu. The metal fill layer may additionally or collectively include other metals, metal oxides, metal nitrides, other suitable materials, or combinations thereof.

Still referring to FIG. 3, the gate structures 108 include a bottom portion 108a disposed below the topmost channel 106a and a top portion 108b disposed over the topmost channel 106a. Inner spacers 105 are disposed along sidewalls of the bottom portion 108a of the gate structure 108 and gate spacers 109 are disposed along sidewalls of the top portion 108b of the gate structure 108. Inner spacers 105 are disposed vertically between channels 106a and laterally between the S/D epitaxial feature 106b and the gate structure 108. Gate spacers 109 land on the topmost channel 106a and may be disposed directly above the inner spacers 105. In some embodiments, the inner spacers 105 include a dielectric material that includes silicon, oxygen, carbon, nitrogen, other suitable material, or combinations thereof (for example, silicon oxide (SiO2), silicon nitride (SiN), silicon oxynitride (SiON), silicon carbide (SiC), or silicon oxycarbonitride (SiOCN). In some embodiments, the inner spacers 105 includes a low-k dielectric material. In some embodiments, the gate spacers 109 may be made of silicon oxide (SiO2), silicon nitride (SiN), silicon oxycarbide (SiOC), silicon oxycarbonitride (SiOCN), silicon carbonitride (SiCN), metal nitride, or a suitable dielectric material. In some embodiments, the inner spacers 105 may include a material that is different from a material of the gate spacers 109 to achieve desired etching selectivity or to achieve different isolation effects.

Still referring to FIG. 3, the semiconductor device 100 includes a first interlayer dielectric (ILD) layer 110 adjacent the gate structures 108 and over the S/D epitaxial features 106b. The first ILD layer 110 laterally surrounds the top portion 108b of the gate structure 108. As shown, the gate spacers 109 are disposed laterally between the first ILD layer 110 and the top portion 108b of the gate structure 108. In the present embodiment, the first ILD layer 110 includes an oxide-based dielectric material such as silicon oxide (SiO2). However, the first ILD layer 110 can include a multilayer structure having multiple dielectric layers. In some embodiments, an etch stop layer (ESL) 111 is disposed vertically between the S/D epitaxial features 106b and the first ILD layer 110 and laterally between and the gate spacers 109 and the ILD layer 110. The ESL 111 includes a material different than the first ILD layer 110, such as a dielectric material that is different than the dielectric material of the first ILD layer 110. For example, where the first ILD layer 110 includes an oxide-based dielectric material, the ESL 111 includes silicon and nitrogen, such as silicon nitride (SiN), silicon carbonitride (SiCN), or silicon oxynitride (SiON).

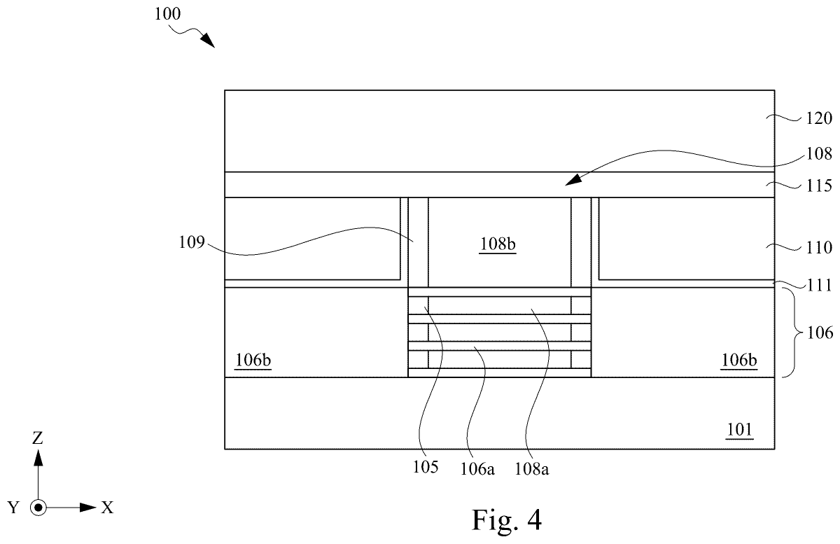

Referring now to FIG. 4, the method 1000 at operation 1004 forms a second ILD layer 120 over the first ILD layer 110 and over the gate structures 108. In the present embodiment, the operation 1004 includes depositing an etch stop layer (ESL) 115 over the first ILD layer 110, then depositing the second ILD layer 120 over the ESL 115. Although separately described, the ESL 115 may also be referred to as part of the second ILD layer 120 (i.e., the second ILD layer 120 is a multilayer structure having multiple dielectric layers including the ESL 115).

The ESL 115 may be formed by any suitable deposition process (such as CVD, PVD, ALD, HDPCVD, MOCVD, RPCVD, PECVD, LPCVD, ALCVD, APCVD, plating, other suitable methods, or combinations thereof). In the present embodiment, the ESL 115 is a nitride-based dielectric layer such as a silicon nitride (SiN) layer or a silicon carbonitride (SiCN) layer. The ESL 115 directly lands on top surfaces of the first ILD layer 110, the gate spacers 109 and the top portion 108b of the gate structures 108.

The second ILD layer 120 may be formed by any suitable deposition process (such as CVD, PVD, ALD, HDPCVD, MOCVD, RPCVD, PECVD, LPCVD, ALCVD, APCVD, plating, other suitable methods, or combinations thereof). The second ILD layer 120 includes similar materials as the first ILD layer 110 (e.g., both ILD layers includes silicon oxide).

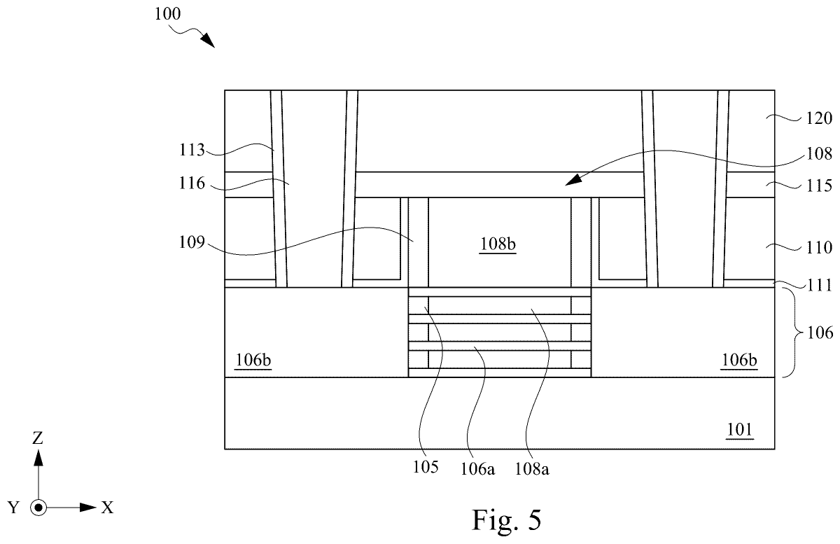

Referring now to FIG. 5, the method 1000 at operation 1006 forms S/D contacts 116 through the first and second ILD layers 110 and 120 to land on the S/D features 106b. As shown, the S/D contacts 116 also penetrates through the ESL 115. The operation 1006 may include first forming S/D contact trenches (not shown) by a patterning process to expose one or more S/D epitaxial features 106b. The patterning process may include lithography and etching, where a patterned mask layer is formed over the IC structure 150, and the S/D contact trenches are formed by etching through openings defined by the patterned mask layer. The etching may be a multi-etch process that separately and sequentially etches through materials of the second ILD layer 120, the ESL 115, the first ILD layer 110, and the ESL 111. For example, each of the first and second ILD layer 120 may be etched through dry etching and the ESLs 115 and 111 may be etched through wet etching. The etchant applied for the first and second ILD layer 120 may be selective in etching an oxide dielectric, and the etchant applied for the ESLs 115 and 113 may be selective in etching a nitride dielectric. After forming the S/D contact trenches, the operation 1006 may deposit one or more conductive materials into the S/D contact trenches. Thereafter, a chemical mechanical planarization (CMP) may be performed to form the S/D contacts 116. The deposited conductive materials may include silicide features and metal fill layers over the silicide features. The silicide features may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds. The metal fill layer over the silicide features may include titanium (Ti), titanium nitride (TiN), ruthenium (Ru), copper (Cu), nickel (Ni), cobalt (Co), tungsten (W), tantalum (Ta), or molybdenum (Mo).

Optionally, the method 1000 at operation 1006 may further include forming barrier layers 113 in the S/D trenches before forming the S/D contacts 116. For example, a barrier liner may be conformally deposited into the S/D trenches, then a dry etching process (e.g., an anisotropic plasma etch) is performed to etch away horizontal portions of the barrier liner, thereby forming the barrier layers 113. The barrier layers 113 line sidewalls of the S/D contacts 116 to prevent metal diffusion into surrounding environment. The barrier layers 113 may include Ti/TiN, SiN, or W. In the present embodiment, the barrier layers 113 include SiN.

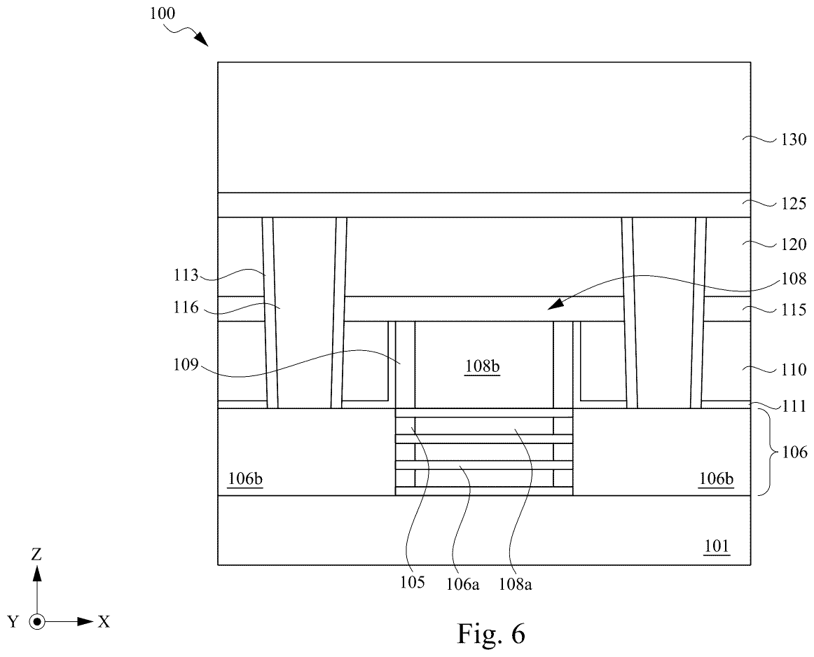

Referring now to FIG. 6, the method 1000 at operation 1008 forms a third ILD layer 130 over the second ILD layer 120 and the S/D contacts 116. In the present embodiment, the operation 1008 includes depositing an etch stop layer (ESL) 125 over the second ILD layer 120, then depositing the third ILD layer 130 over the ESL 125. Although separately described, the ESL 125 may also be referred to as part of the third ILD layer 130 (i.e., the third ILD layer 130 is a multilayer structure having multiple dielectric layers including the ESL 125).

The ESL 125 may be formed by any suitable deposition process (such as CVD, PVD, ALD, HDPCVD, MOCVD, RPCVD, PECVD, LPCVD, ALCVD, APCVD, plating, other suitable methods, or combinations thereof). In the present embodiment, the ESL 125 is a nitride-based dielectric layer such as a silicon nitride (SiN) layer or a silicon carbonitride (SiCN) layer. The ESL 125 directly lands on top surfaces of the second ILD layer 120, the barrier layers 113 (if present) and the S/D contacts 116.

The third ILD layer 130 may be formed by any suitable deposition process (such as CVD, PVD, ALD, HDPCVD, MOCVD, RPCVD, PECVD, LPCVD, ALCVD, APCVD, plating, other suitable methods, or combinations thereof). The third ILD layer 130 includes similar materials as the first ILD layer 110 (e.g., both ILD layers includes silicon oxide).

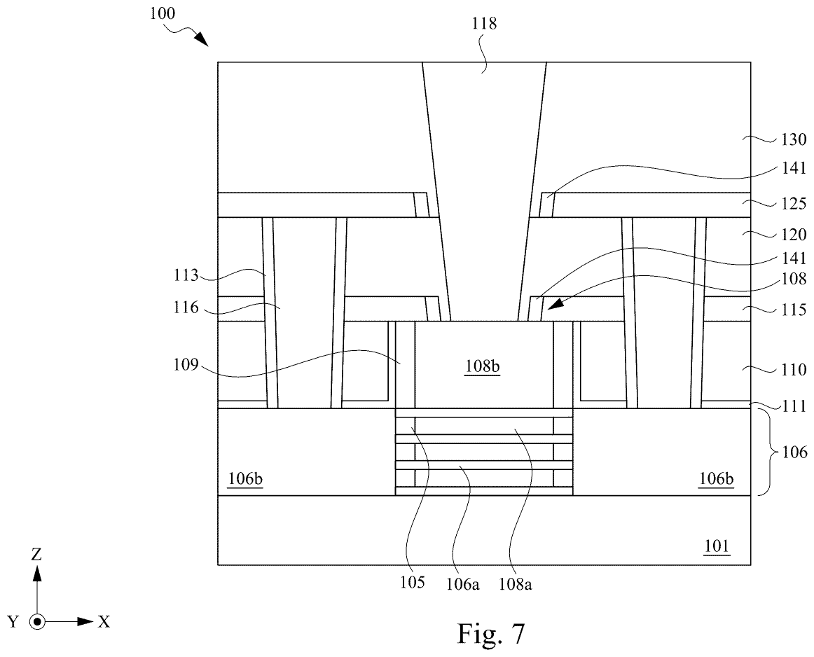

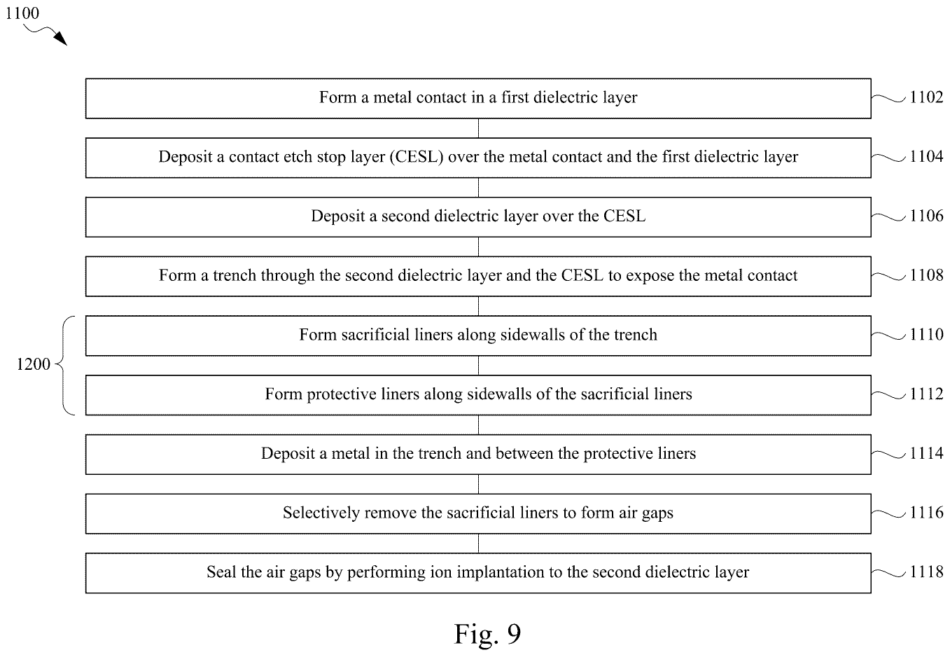

Referring now to FIG. 7, the method 1000 at operation 1010 forms gate contacts 118 through the second and third ILD layers 120 and 130 to land on the gate structures 108, the gate contacts 118 are isolated from one or more etch stop layers (ESLs) (e.g., ESLs 115 and/or 125) by one or more air gaps 141. As shown, the gate contacts 118 also penetrates through the ESLs 115 and 125. The operation 1010 may include first forming gate contact trenches (not shown) by a patterning process to expose one or more gate structures 108. The patterning process may include lithography and etching, where a patterned mask layer is formed over the IC structure 150, and the gate contact trenches are formed by etching through openings defined by the patterned mask layer. After forming the gate contact trenches, the operation 1010 may deposit one or more conductive materials into the gate contact trenches. The deposition may be a bottom-up metal growth process, which has superior gap filling capabilities to avoid forming voids in the gate contacts 118. The bottom-up metal growth process is described further with respect to method 1100 in FIG. 9. After depositing the one or more conductive materials, a chemical mechanical planarization (CMP) may be performed to form the gate contacts 118. The deposited conductive materials may include W, Ti/TiN, Ru, Mo, or combinations thereof. In an embodiment, the gate contacts 118 includes a multi-grain metal with impurity. In another embodiment, the gate contacts 118 are made of single-grain pure metal such as pure Mo.

The operation 1010 forms the gate contacts 118 isolated and separated from the ESLs (e.g., ESLs 115 and/or 125). This is further described with respect to method 1100 in FIG. 9. As shown, the gate contacts 118 may be laterally separated from the ESLs (e.g., ESLs 115 and/or 125) by portions of the respective ILD layers 120 and 130 and by air gaps 141. The portions of the respective ILD layers 120 and 130 are protective liner portions that directly interface sidewalls of the gate contacts 118.

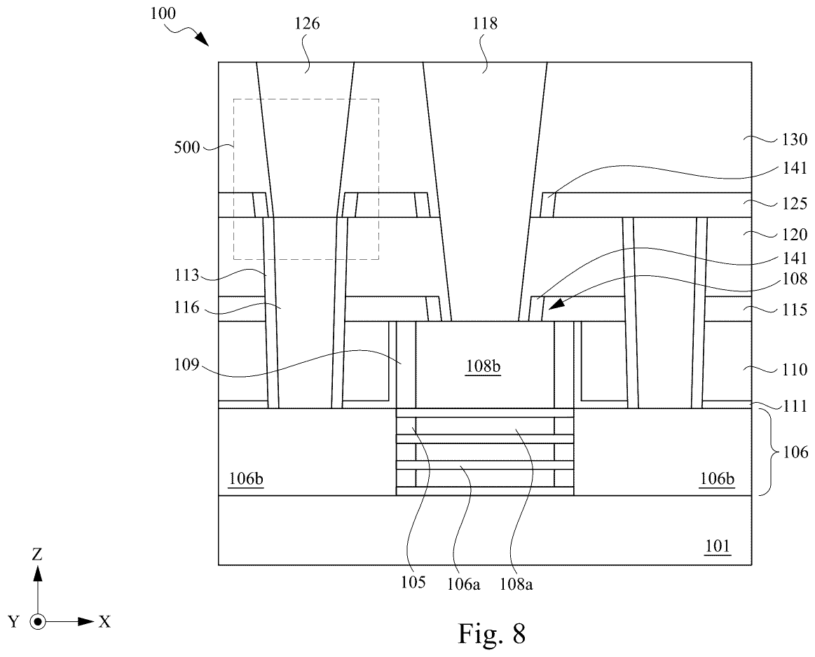

Referring now to FIG. 8, the method 1000 at operation 1012 forms S/D vias 126 through the third ILD layer 130 to land on the S/D contacts 116, the S/D vias 126 are isolated from one or more etch stop layers (ESLs) (e.g., ESL 125) by one or more air gaps 141. As shown, the S/D vias 126 also penetrates through the ESL 125. The operation 1012 may include first forming S/D via trenches (not shown) by a patterning process to expose one or more S/D contacts 116. The patterning process may include lithography and etching, where a patterned mask layer is formed over the IC structure 150, and the S/D via trenches are formed by etching through openings defined by the patterned mask layer. After forming the S/D via trenches, the operation 1012 may deposit one or more conductive materials into the S/D via trenches. The deposition may be a bottom-up metal growth process, which has superior gap filling capabilities to avoid forming voids in the S/D vias 126. The bottom-up metal growth process is described further with respect to method 1100 in FIG. 9. After depositing the one or more conductive materials, a chemical mechanical planarization (CMP) may be performed to form the S/D vias 126. The deposited conductive materials may include W, Ti/TiN, Ru, Mo, or combinations thereof. In an embodiment, the S/D vias 126 includes a multi-grain metal with impurity. In another embodiment, the S/D vias 126 are made of single-grain pure metal such as pure Mo.

The operation 1012 forms the S/D vias 126 isolated and separated from the ESLs (e.g., ESL 125). This is further described with respect to method 1100 in FIG. 9. As shown, the S/D vias 126 may be laterally separated from the ESL 125 by portions of the respective ILD layer 130 and by air gaps 141. The portions of the respective ILD layer 130 are protective liner portions that directly interface sidewalls of the S/D vias 126.

In the present embodiments, the ILD layers 110, 120, and 130 include different dielectric materials from the ESLs 111, 115, and 125. For example, the ILD layers 110, 120, and 130 are made of an oxide-based dielectric such as silicon oxide and the ESLs 115 and 125 are made of a nitride-based dielectric such as silicon nitride or silicon carbonitride. This allows for etchant selectivity when forming various conductive plugs (i.e., vias and contacts) through the different ILD and ESL layers. Further, the ESLs 111, 115, and 125 are thinner than the respective ILD layers 110, 120, and 130 along the z direction. In the present embodiment, the ILD layer 110 is thicker than the ILD layer 120 along the z direction.

Additional operations can be provided before, during, and after method 1000, and some of the operations described can be moved, replaced, or eliminated for additional embodiments of method 1000. For example, the method 1000 may further include forming an interconnect structure over the third ILD layer 130. The interconnect structure may include features that electrically couple various devices (for example, p-type GAA transistors and/or n-type GAA transistors of the device 100, resistors, capacitors, and/or inductors) and/or components (for example, gate structures 108 and/or epitaxial source/drain features 106b of p-type GAA transistors and/or n-type GAA transistors), such that the various devices and/or components can operate as specified by design requirements of the device 100.

The interconnect structure includes a combination of dielectric layers (i.e., intermetal dielectric layers and ESLs) and electrically conductive layers (e.g., metal layers) configured to form various interconnect layers. The conductive layers are configured to form vertical interconnect features, such as vias, and/or horizontal interconnect features, such as conductive lines. Vertical interconnect features typically connect horizontal interconnect features in different layers (or different planes) of the interconnect structure. The various horizontal and vertical interconnect feature may electrically connect to the device-level contacts (e.g., S/D vias 126 and gate contacts 118) formed in the third ILD layer 130. Note that the interconnect structure may include intermetal vias that are also laterally separated from ESLs, according to methods described herein. During operation, the interconnect structure is configured to route signals between the devices and/or the components of the device 100 and/or distribute signals (for example, clock signals, voltage signals, and/or ground signals) to the devices and/or the components of the device 100.

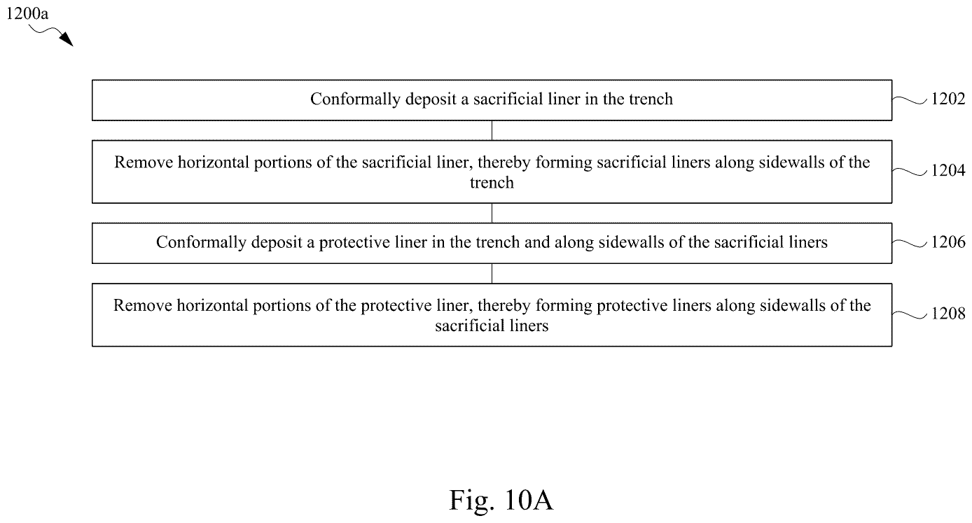

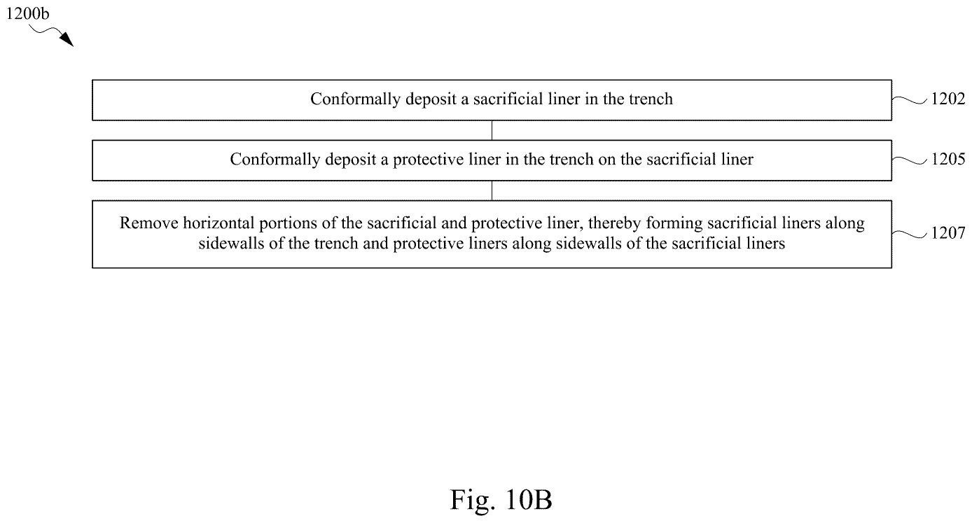

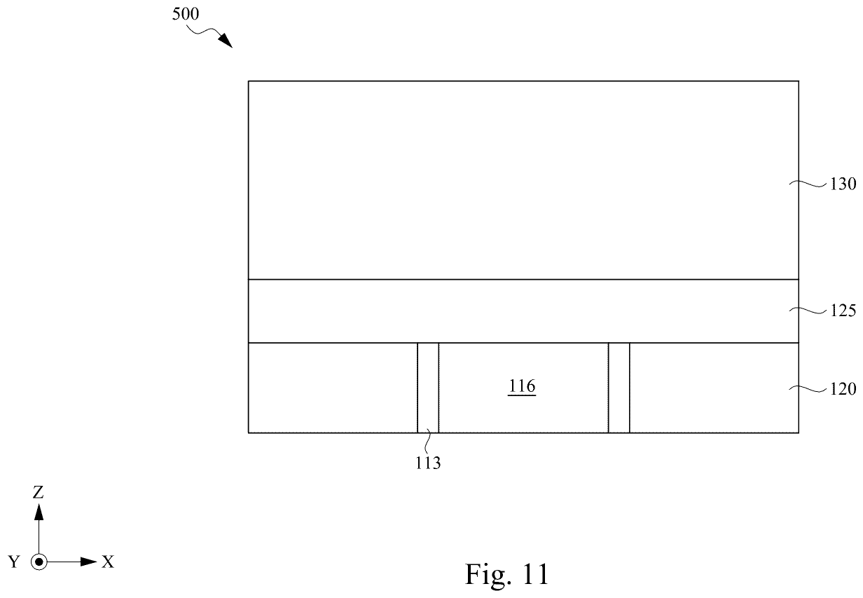

FIG. 9 illustrates a flow chart of a method 1100 to form metal vias or contacts (e.g., S/D vias 126 and gate contacts 118) isolated from etch stop layers (e.g., ESLs 115 and 125), in portion or in entirety, according to an embodiment of the present disclosure. FIGS. 10A-10B illustrate different method embodiments 1200a and 1200b of forming sacrificial and protective liners as part of the method 1100 of FIG. 9. The method 1100 is described below with reference to FIGS. 11-19, 20A-20B, 21-28, and 29A-29B. These figures illustrate a film stack of the device 100 that includes an ILD and ESL over a conductive feature. In the present embodiment, these figures correspond to the region 500 shown in FIG. 8 (i.e., surrounding the S/D vias 126). Note however, these figures may also correspond to other regions shown in FIG. 8 (e.g., surrounding the gate contacts 118), or other regions not shown in FIG. 8 (e.g., surrounding intermetal vias in a frontside interconnect structure).

FIGS. 11-19 illustrate cross-sectional views of a film stack of semiconductor device 100 processed in accordance with the methods of FIGS. 9 and 10A, according to an embodiment of the present disclosure.

Referring now to FIG. 11, the method 1100 at operation 1102 forms a metal contact (e.g., S/D contact 116) in a first dielectric layer (e.g., ILD layer 120). The metal contact may be lined with barrier layers (e.g., barrier layers 113) along its sidewalls. Operation 1102 may correspond to operation 1006 previously described.

Still referring to FIG. 11, the method 1100 at operation 1104 deposits an etch stop layer (ESL) (e.g., ESL 125) over the metal contact (e.g., S/D contact 116) and the first dielectric layer (e.g., ILD layer 120). In an embodiment, the ESL is a nitride-based dielectric such as silicon nitride (SiN). In an embodiment, the ESL is a low-k ESL (e.g., SiCN) to minimize stray capacitance coupling. Operation 1104 may correspond to operation 1008 previously described.

Still referring to FIG. 11, the method 1100 at operation 1106 deposits a second dielectric layer (e.g., ILD layer 130) over the ESL (e.g., ESL 125). As a result, a film stack is formed where the ESL is disposed vertically between the first and the second dielectric layers (e.g., ILD layers 120 and 130). In an embodiment, the first and the second dielectric layers include an oxide-based dielectric such as silicon oxide (SiOx). Operation 1106 may correspond to operation 1008 previously described.

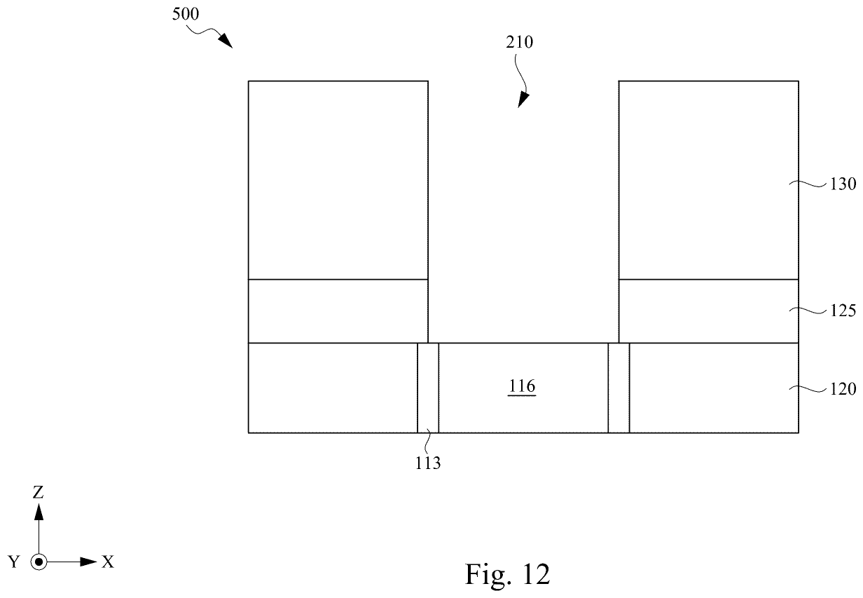

Referring now to FIG. 12, the method 1100 at operation 1108 forms a trench 210 through the second dielectric layer (e.g., ILD layer 130) and the ESL (e.g., ESL 125) to expose the metal contact (e.g., S/D contact 116). The trench 210 may be formed may be formed through photolithography and etching processes. For example, the photolithography process may form a masking element covering areas of the device 100 that are not to be etched and exposing areas that are to be etched. Then, an etching process is performed to etch through the exposed areas. In the present embodiment, the trench 210 is formed wider in the x direction than the metal contact (e.g., S/D contact 116). This creates the necessary spacing to form air spacers and protective liners that isolates the later-formed metal via (or contact) in the trench 210 from the adjacent ESL (e.g., ESL 125).

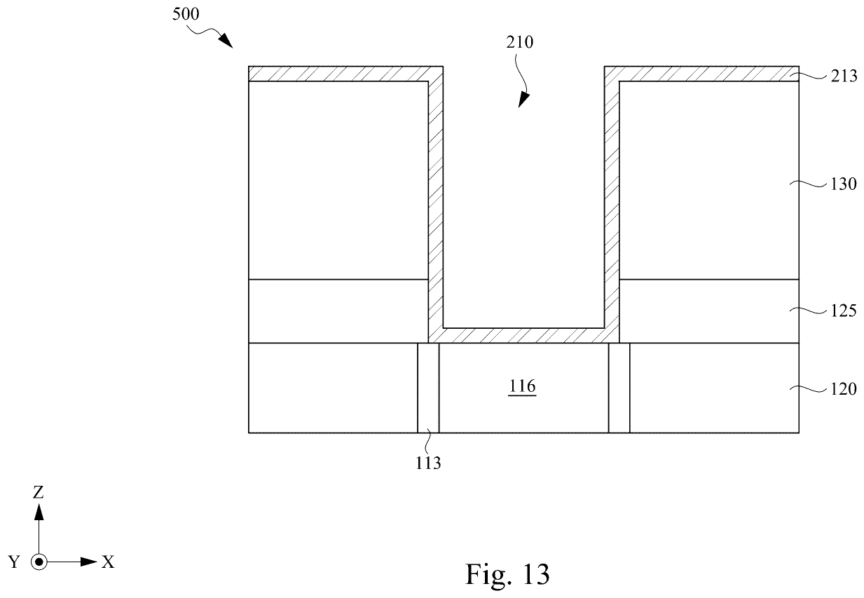

Referring now to FIGS. 13-16, the method 1100 at operations 1110 and 1112 form sacrificial liners 213 along sidewalls of the trench 210 and protective liners 230 along sidewalls of the sacrificial liners 213. The operations 1110 and 1112 are collectively referred to as method 1200, which is further described in FIG. 10A according to a first embodiment 1200a. The first embodiment 1200a is described below with reference to FIGS. 13-16.

Referring to FIG. 13, the method 1200 at operation 1202 conformally deposits a sacrificial liner 213 in the trench 210 (e.g., through CVD). The sacrificial liner 213 lands on top and side surfaces of the second dielectric layer (e.g., ILD layer 130), side surfaces of the ESL (e.g., ESL 125), a bottom surface of the metal contact (e.g., S/D contact 116), and barrier layers 113 (if present). The sacrificial liner 213 has a different material from its surrounding features (e.g., ILD layer 130 and ESL 125). This is so that it can later be selectively etched away without damaging the surrounding features. In the present embodiment, the sacrificial liner 213 is a dummy silicon liner. The silicon liner may include amorphous silicon or polysilicon.

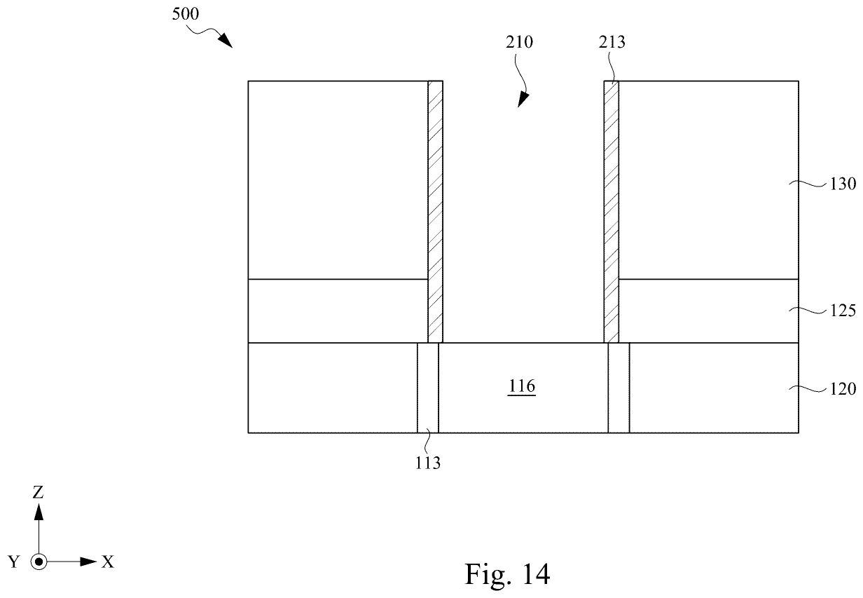

Referring to FIG. 14, the method 1200 at operation 1204 removes horizontal portions of the sacrificial liner 213, thereby forming sacrificial liners 213 along sidewalls of the trench 210. Operation 1204 includes an anisotropic etch (e.g., plasma etch) that selectively etches portions of the sacrificial liner 213 landing on the top surface of the second dielectric layer (e.g., ILD layer 130) and on the top surface of the metal contact (e.g., S/D contact 116). In an embodiment, a thickness along the x direction of the sacrificial liners 213 ranges between about 2 nm to about 4 nm. If the thickness is too thin, the air gaps later formed will be too small to achieve noticeable effective capacitance improvements. If the thickness is too thick, the ILD sealing later performed may fail.

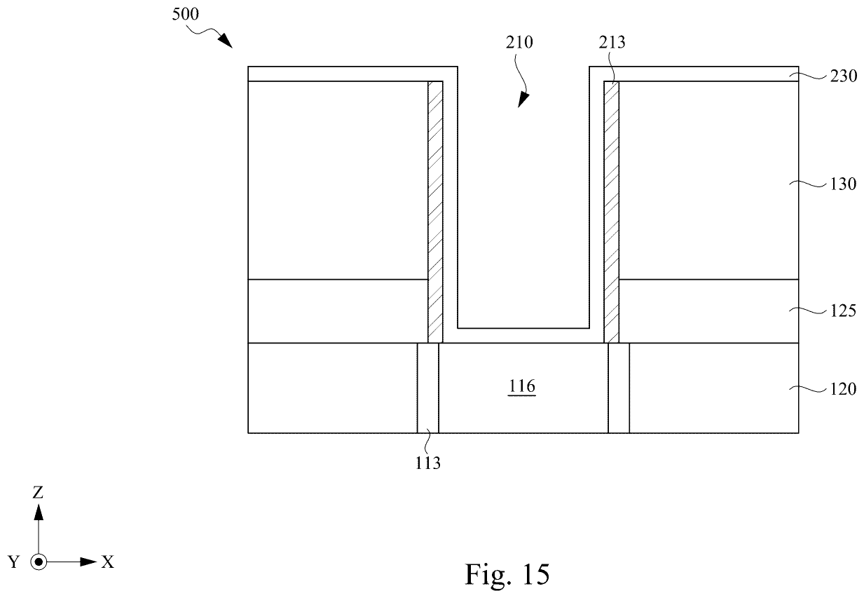

Referring to FIG. 15, the method 1200 at operation 1206 conformally deposits a protective liner 230 (e.g., through CVD) in the trench 210 and along sidewalls of the sacrificial liners 213. The protective liner 230 lands on a top surface of the second dielectric layer (e.g., ILD layer 130), side surfaces of sacrificial liners 213, and a bottom surface of the metal contact (e.g., S/D contact 116). The protective liner 230 acts as a barrier layer for the later-deposited metal. The protective liner 230 reduces bottom-up metal selective loss by preventing the later-deposited metal from reacting with impurities in the ESL 125 and/or surrounding features. For example, the protective liner 230 prevents any carbon exposed in the trench 210 from impacting the bottom-up metal growth process. In the present embodiment, the protective liner 230 includes silicon oxide (SiOx). The protective liner 230 later become part of the second dielectric layer (e.g., ILD layer 130) after ILD sealing.

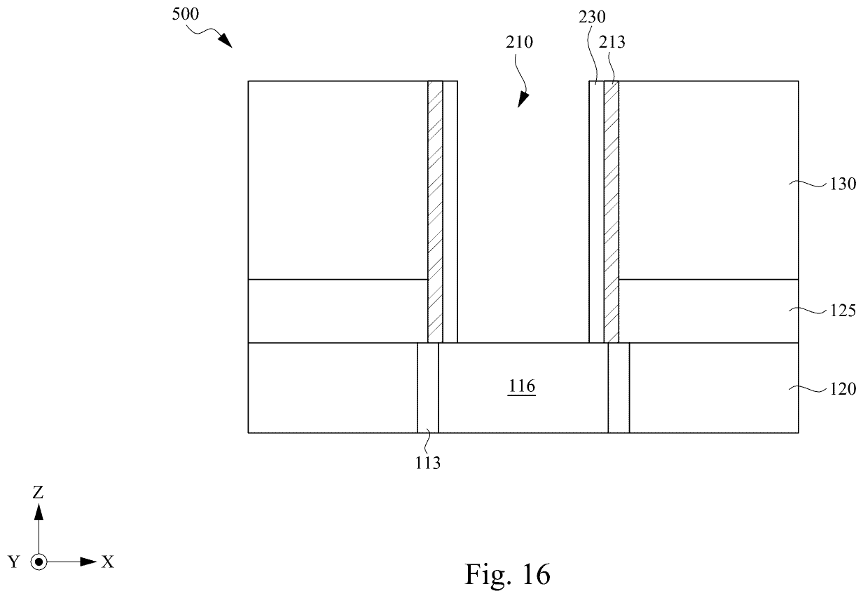

Referring to FIG. 16, the method 1200 at operation 1208 removes horizontal portions of the protective liner 230, thereby forming protective liners 230 along sidewalls of the sacrificial liners 213. Operation 1208 includes an anisotropic etch (e.g., plasma etch) that selectively etches portions of the protective liner 230 landing on the top surface of the second dielectric layer (e.g., ILD layer 130) and on the top surface of the metal contact (e.g., S/D contact 116). In an embodiment, a thickness along the x direction of the protective liners 230 ranges between about 2 nm to about 4 nm. If the thickness is too thin, the protective liners 230 do not provide adequate protection to prevent selective metal loss. If the thickness is too thick, there is less surface contact between the metal contact (e.g., S/D contact 116) and the later-formed metal vias or contacts (e.g., S/D via 126).

As a result of operation 1208, and in accordance with the first embodiment 1200a, a bilayer liner structure is formed along sidewalls of the trench 210, where both bottom surfaces of the sacrificial liners 213 and the protective liners 230 are coplanar (or substantially coplanar), and both sacrificial liners 213 and the protective liners 230 have a same (or substantially same) vertical height. The first embodiment 1200a involves an etch step after each deposition of the respective liners, resulting in the structure shown in FIG. 16. After the operation 1208, the method 1100 continues to operation 1114.

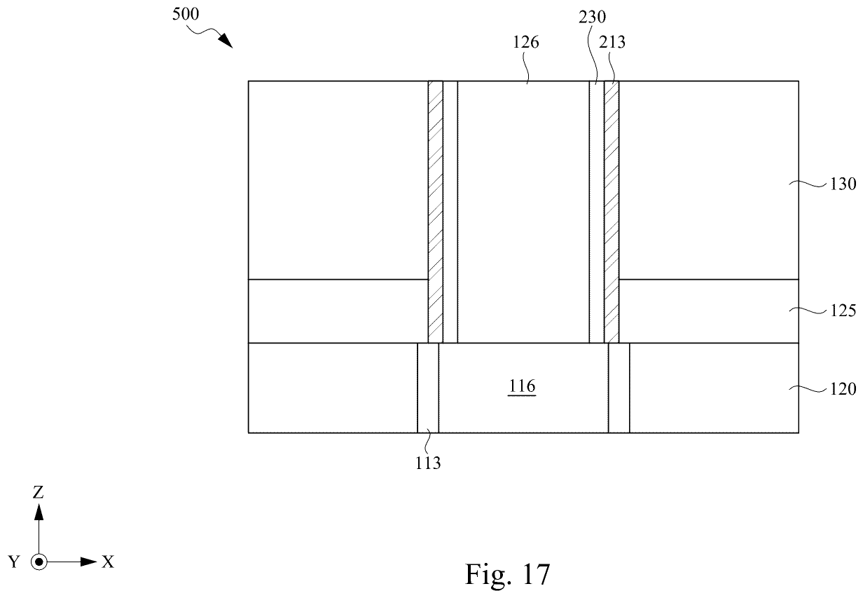

Referring to FIG. 17, the method 1100 at operation 1114 deposits a metal (e.g., S/D via 126) in the trench 210 and between the protective liners 230. The metal is deposited through bottom-up metal growth. Bottom-up metal growth is also referred to as bottom-up anisotropic deposition, where metal layers are deposited sublayer by sublayer through applying metal precursors and facilitating a vertical metal growth. In some embodiments, the bottom-up metal growth includes applying halogen components to facilitate simultaneous deposition and etch. Bottom-up metal growth may have advantages over isotropic metal deposition by achieving greater metal density and avoiding metal seams. However, in bottom-up metal growth, issues of selective metal loss may occur when the deposited metal directly contacts and reacts with impurities, such as carbon impurities in a SiCN low-k ESL. The protective liners 230 do not include impurities and further prevents impurities from contacting the deposited metal, thereby eliminating or reducing risks of metal selective loss.

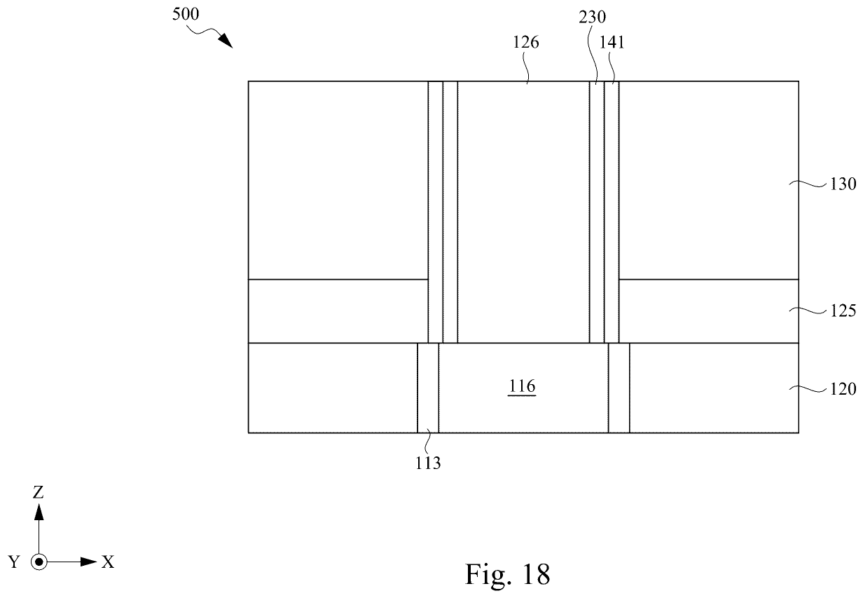

Referring to FIG. 18, the method 1100 at operation 1116 selectively removes the sacrificial liners 213 to form air gaps 141 (also referred to as air spacers or air walls). Operation 1116 includes applying an etchant that targets etching the sacrificial liners 213 without substantially etching the surrounding features (e.g., by having etch selectivity greater than 10 when compared to surrounding features such as the protective liners 230, the second dielectric layer (e.g., ILD layer 130), and the ESL (e.g., ESL 125)). The etching process may be a dry etching process, a wet etching process, other suitable etching process, or combinations thereof. The air gaps reduce stray capacitance coupling by lowering the capacitance of the ESL (e.g., from 3.8 to 1 when the ESL includes SiCN).

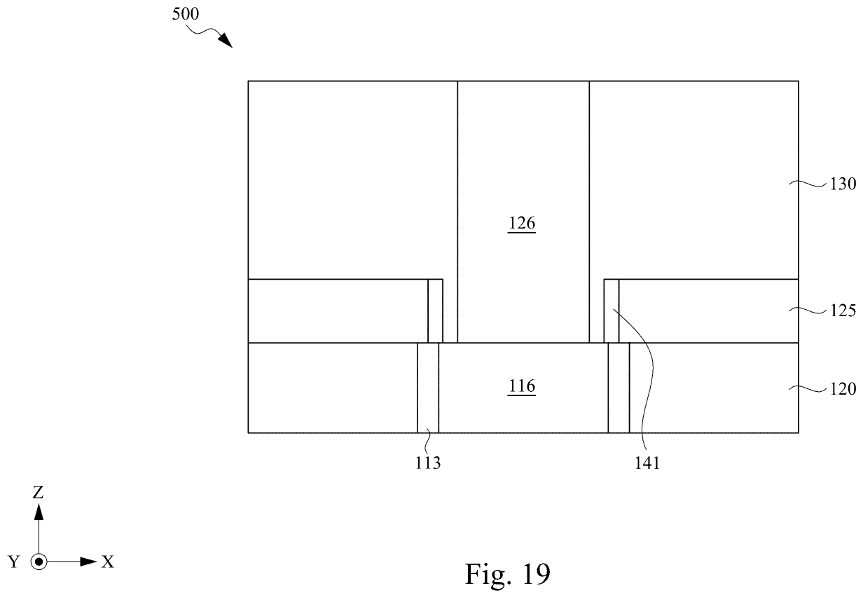

Referring to FIG. 19, the method 1100 at operation 1118 seals the air gaps 141 by performing ion implantation to the second dielectric layer (e.g., ILD layer 130). The ion implantation expands the second dielectric layer such that the second dielectric layer laterally merges with the protective liners 230. As a result, the protective liners 230 become part of the second dielectric layer. Note that the second dielectric layer (e.g., ILD layer 130) is chosen with a composition to effectively achieve the expansion for air gap sealing by the ion implantation process. The ion implantation introduces one or more dopant to the second dielectric layer, thereby converting the second dielectric layer into an implanted second dielectric layer that laterally seals the air gaps 141. For example, the ion implantation may include germanium (Ge) implantation with energy ranging between 10 keV to 20 keV and at dosage ranging from 1E1 to 3E 14 atoms/cm2. In an alternative (or further) embodiment, the ion implantation may include arsenic (As) or Tin (Sn) implantation with similar energy and dosage. In an embodiment, the first and the second dielectric layers (e.g., ILD layers 120 and 130) each include silicon oxide, where the second ILD layer (e.g., ILD layer 130) further includes germanium (and/or arsenic), and a top portion of the second ILD layer has a greater concentration of germanium (and/or arsenic) than a bottom portion of the second ILD layer. In an embodiment, the top portion of the second ILD layer seals the air gap. As a result of the sealing, the sealed air gap 141 results in a reduced height. In the embodiment of FIG. 19, there is complete lateral expansion of the second dielectric layer (e.g., ILD layer 130), and the sealed air gap 141 has a height substantially similar to that of the ESL (e.g., ESL 125). In an embodiment, a top surface of the air gaps 141 are substantially coplanar with a top surface of the ESL.

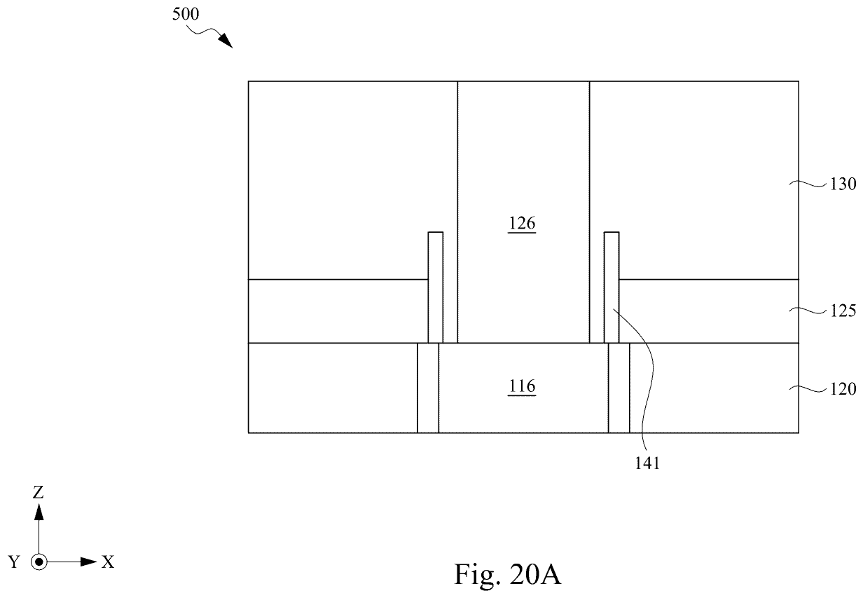

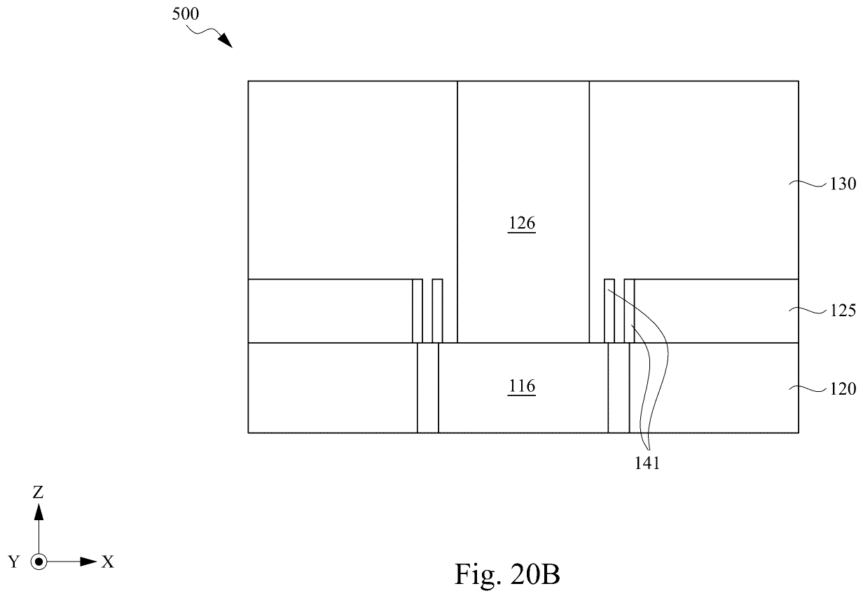

FIGS. 20A-20B illustrate metal vias or contacts (e.g., S/D via 126) isolated from etch stop layers (e.g., ESL 125), according to further embodiments of the present disclosure. Note that in the embodiments of FIGS. 20A-20B, the device 100 is processed according to the first embodiment 1200a described in FIG. 10A.

Referring to FIG. 20A, operation 1118 may be tuned such that the sealed air gaps 141 have a height above or below the ESL. For example, implantation at a lower energy and/or dosage may only laterally expand a top portion of the second dielectric layer (e.g., ILD layer 130), while a bottom portion remain nonimplanted. As a result, only the top portion of the second dielectric layer (e.g., ILD layer 130) laterally expands to interface the protective liners 230. In this case, as shown in FIG. 20A, the sealed air gaps 141 have a greater height than the ESL. For another example, implantation at a higher energy and/or dosage may further push the already fully laterally expanded second dielectric layer (e.g., ILD layer 130) into bottom portions of the air gaps 141. In this case, the sealed air gaps 141 have a lower height than the ESL (not shown).

Referring to FIG. 20B, in further embodiments, multiple air gaps 141 may be formed between a metal via or contact (e.g., S/D via 126) and a ESL (e.g., ESL 125). For example, instead of forming a bi-layer structure of sacrificial liners 213 and protective liners 230, a quad-layer structure of alternating sacrificial liners 213, protective liners 230, sacrificial liners 213, and protective liners 230 is formed. And the two sacrificial liners 213 of the quad-layer are selectively removed, while the two protective liners 230 remain and become part of the second dielectric layer (e.g., ILD layer 130) after ion implantation. In these embodiments, greater reduction to parasitic capacitance may be achieved. Although not shown, like in the embodiment of FIG. 20A, the multiple air gaps 141 may also have heights above or below the ESL.

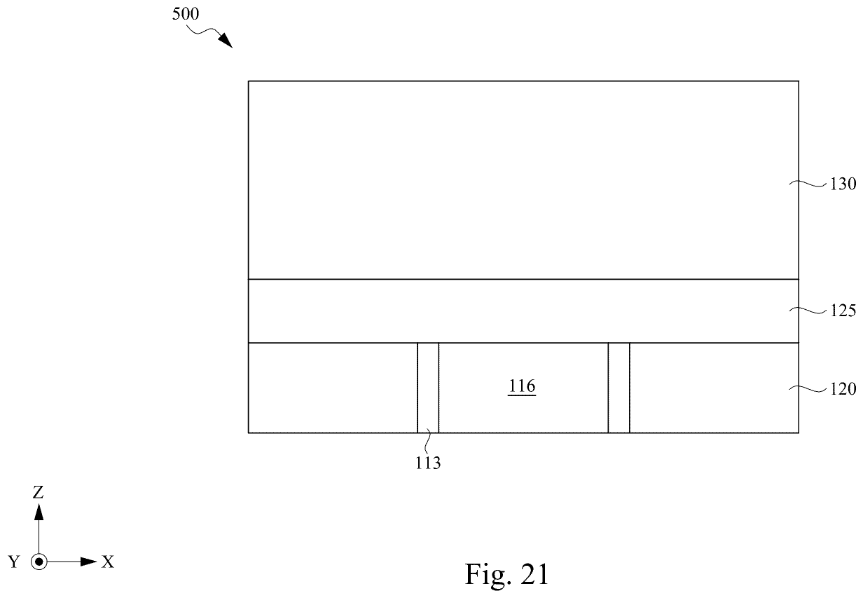

FIGS. 21-28 illustrate cross-sectional views of a film stack of semiconductor device 100 processed in accordance with the methods of FIGS. 9 and 10B, according to another embodiment of the present disclosure. The methods of FIGS. 9 and 10B is similar to the methods of FIGS. 9 and 10A described with respect to FIGS. 11-19. Some of the similar features will not be repeated for the sake of brevity.

Referring to FIG. 21, the method 1100 at operation 1102-1106 forms a ESL (e.g., ESL 125) over a metal contact (e.g., S/D contact 116) and a first dielectric layer (e.g., ILD layer 120). The operations 1102-1106 further forms a second dielectric layer (e.g., ILD layer 130) over the ESL.

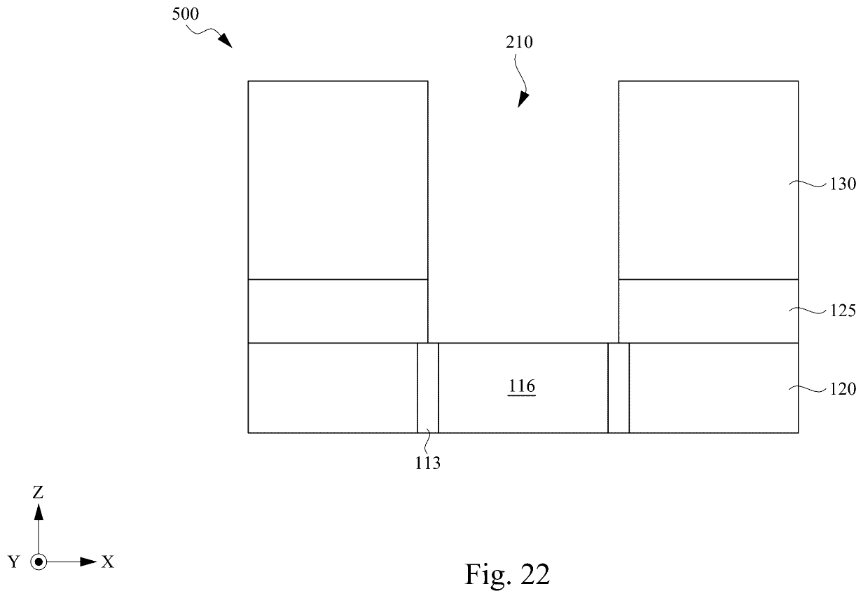

Referring to FIG. 22, the method 1100 at operation 1108 forms a trench 210 through the second dielectric layer (e.g., ILD layer 130) and the ESL (e.g., ESL 125) to expose the metal contact (e.g., S/D contact 116).

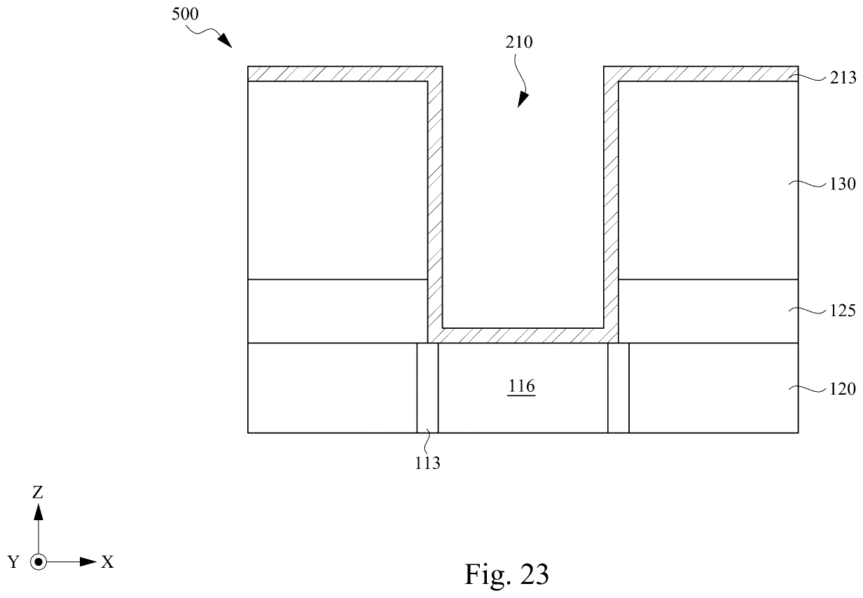

Referring now to FIGS. 23-25, the method 1100 at operations 1110 and 1112 form sacrificial liners 213 along sidewalls of the trench 210 and protective liners 230 along sidewalls of the sacrificial liners 213. The operations 1110 and 1112 are collectively referred to as method 1200, which is further described in FIG. 10B according to a second embodiment 1200b. The second embodiment 1200b is described below with reference to FIGS. 23-25.

Referring to FIG. 23, the method 1200 at operation 1202 conformally deposits a sacrificial liner 213 in the trench 210 (e.g., through CVD). The sacrificial liner 213 lands on top and side surfaces of the second dielectric layer (e.g., ILD layer 130), side surfaces of the ESL (e.g., ESL 125), a bottom surface of the metal contact (e.g., S/D contact 116), and barrier layers 113 (if present). The sacrificial liner 213 has a different material from its surrounding features (e.g., ILD layer 130 and ESL 125). This is so that it can later be selectively etched away without damaging the surrounding features. In the present embodiment, the sacrificial liner 213 is a dummy silicon liner. The silicon liner may include amorphous silicon or polysilicon.

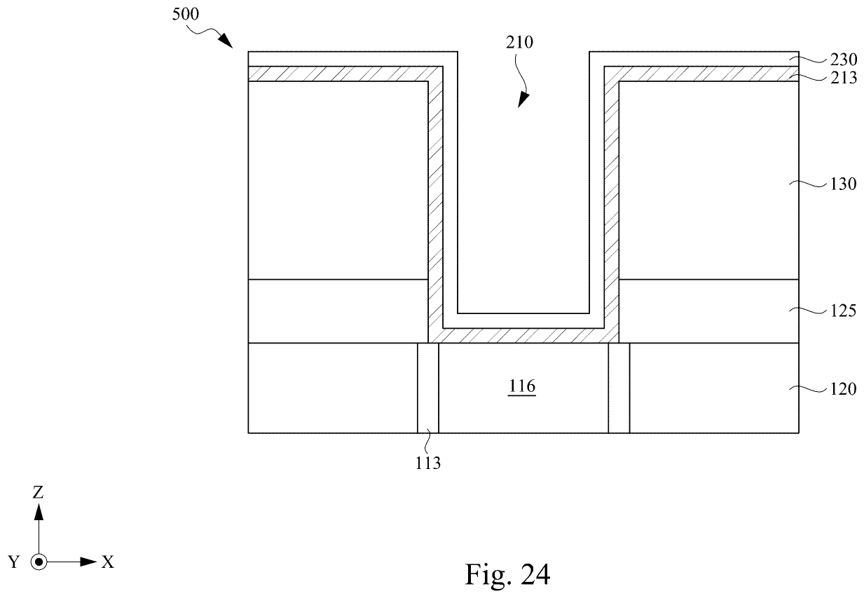

Referring to FIG. 24, the method 1200 at operation 1205 conformally deposits a protective liner 230 in the trench 210 (e.g., through CVD) and on the sacrificial liner 213. The protective liner 230 lands on top, bottom, and side surfaces of the sacrificial liner 213. The protective liner 230 acts as a barrier layer for the later-deposited metal. The protective liner 230 reduces bottom-up metal selective loss by preventing the later-deposited metal from reacting with impurities in the ESL 125 and/or surrounding features. For example, the protective liner 230 prevents any carbon exposed in the trench 210 from impacting the bottom-up metal growth process. In the present embodiment, the protective liner 230 includes silicon oxide (SiOx). The protective liner 230 later become part of the second dielectric layer (e.g., ILD layer 130) after ILD sealing.

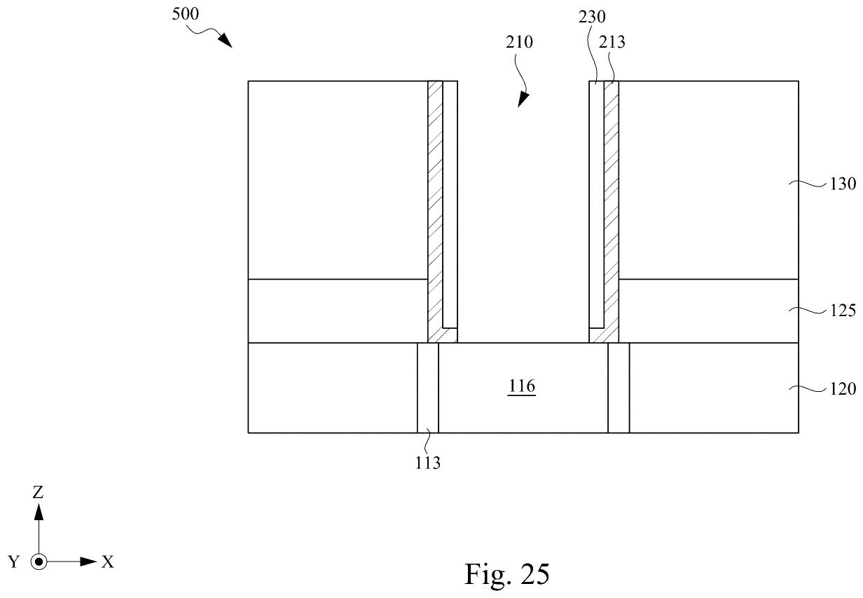

Referring to FIG. 25, the method 1200 at operation 1207 removes horizontal portions of the sacrificial and protective liners 213 and 230, thereby forming sacrificial liners along sidewalls of the trench 210 and protective liners 230 along sidewalls of the sacrificial liners 213. Operation 1208 includes an anisotropic etch (e.g., plasma etch) that selectively etches portions of the sacrificial and protective liners 213 and 230 over the top surface of the second dielectric layer (e.g., ILD layer 130) and over the top surface of the metal contact (e.g., S/D contact 116).

As a result of operation 1207, and in accordance with the second embodiment 1200b, a bilayer liner structure is formed along sidewalls of the trench 210. However, different from the first embodiment 1200a, the sacrificial liners 213 and the protective liners 230 do not have a same or substantially same vertical height. The sacrificial liners 213 have a greater height than the protective liners 230, and the protective liners 230 may land on small horizontal portions of the sacrificial liners 213. The small horizontal portions have a same or similar width as the protective liners 230. This is because the second embodiment only involves one etch step after deposition of both the respective liners, resulting in sacrificial liners 213 having an “L” shape, as shown in the structure of FIG. 25. After the operation 1208, the method 1100 continues to operation 1114.

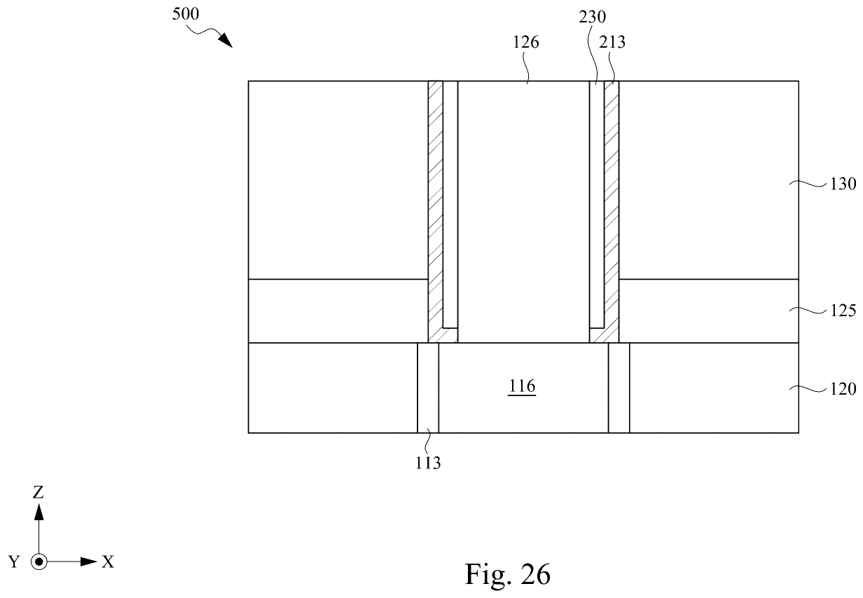

Referring to FIG. 26, the method 1100 at operation 1114 deposits a metal (e.g., S/D via 126) in the trench 210 and between the protective liners 230. The metal is deposited through bottom-up metal growth. Bottom-up metal growth is also referred to as bottom-up anisotropic deposition, where metal layers are deposited sublayer by sublayer through applying metal precursors and facilitating a vertical metal growth. In some embodiments, the bottom-up metal growth includes applying halogen components to facilitate simultaneous deposition and etch. Bottom-up metal growth may have advantages over isotropic metal deposition by achieving greater metal density and avoiding metal seams. However, in bottom-up metal growth, issues of selective metal loss may occur when the deposited metal directly contacts and reacts with impurities, such as carbon impurities in a SiCN low-k ESL. The protective liners 230 do not include impurities and further prevents impurities from contacting the deposited metal, thereby eliminating or reducing risks of metal selective loss. In the embodiment of FIG. 26, the deposited metal may partially contact the exposed small horizontal portions of the sacrificial liners 213. Such contact is minimal and does not pose risks to metal selective loss.

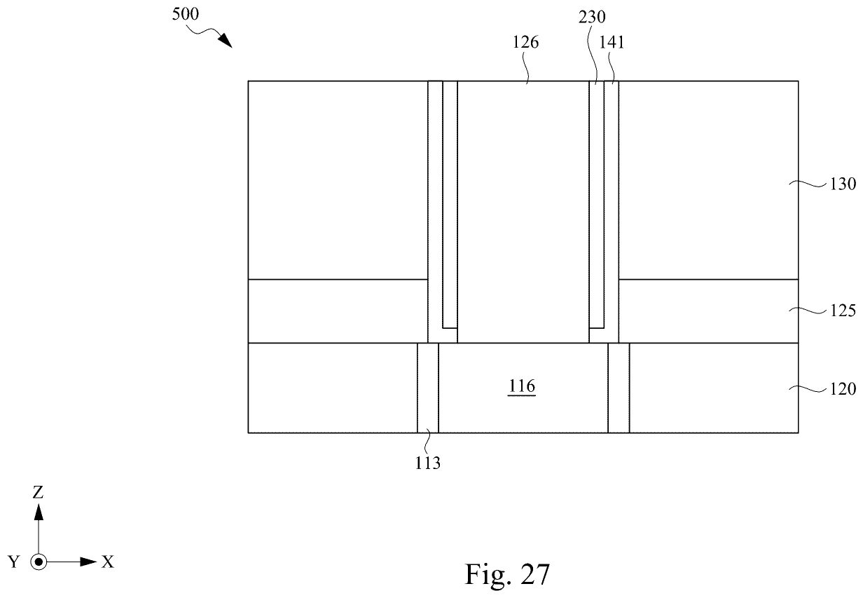

Referring to FIG. 27, the method 1100 at operation 1116 selectively removes the sacrificial liners 213 to form air gaps 141 (also referred to as air spacers or air walls). Operation 1116 includes applying an etchant that targets etching the sacrificial liners 213 without substantially etching the surrounding features (e.g., having etch selectivity greater than 10 when compared to surrounding features such as the protective liners 230, the second dielectric layer (e.g., ILD layer 130), and the ESL (e.g., ESL 125). The etching process may be a dry etching process, a wet etching process, other suitable etching process, or combinations thereof. The air gaps reduce stray capacitance coupling by lowering the capacitance of the ESL (e.g., from 3.8 to 1 when the ESL includes SiCN). Note that in this embodiment, the air gaps 141 have an “L” shape with horizontal portions that partially expose a sidewall of the deposited metal. As such, there is a greater air separation for additional stray capacitance reduction.

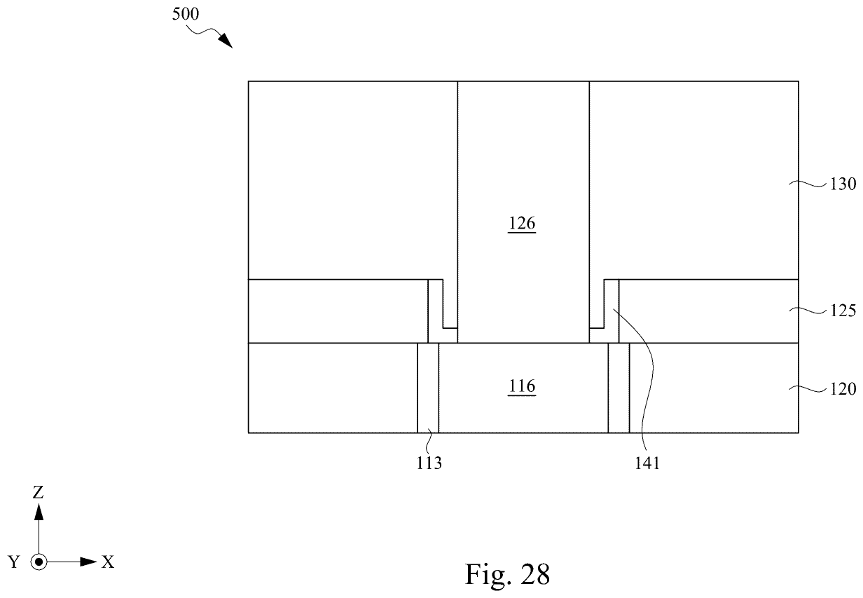

Referring to FIG. 28, the method 1100 at operation 1118 seals the air gaps 141 by performing ion implantation to the second dielectric layer (e.g., ILD layer 130). The ion implantation expands the second dielectric layer such that the second dielectric layer laterally merges with the protective liners 230. As a result, the protective liners 230 become part of the second dielectric layer. Note that the second dielectric layer (e.g., ILD layer 130) is chosen with a composition to effectively achieve the expansion for air gap sealing by the ion implantation process. The ion implantation introduces one or more dopant to the second dielectric layer, thereby converting the second dielectric layer into an implanted second dielectric layer that laterally seals the air gaps 141. For example, the ion implantation may include germanium (Ge) implantation with energy ranging between 10 keV to 20 keV and at dosage ranging from 1E14 to 3E14 atoms/cm2. As a result of the sealing, the sealed air gap 141 results in a reduced height. In the embodiment of FIG. 19, there is complete lateral expansion of the second dielectric layer (e.g., ILD layer 130), and the sealed air gap 141 has a height substantially similar to that of the ESL (e.g., ESL 125). In an embodiment, a top surface of the air gaps 141 are substantially coplanar with a top surface of the ESL.

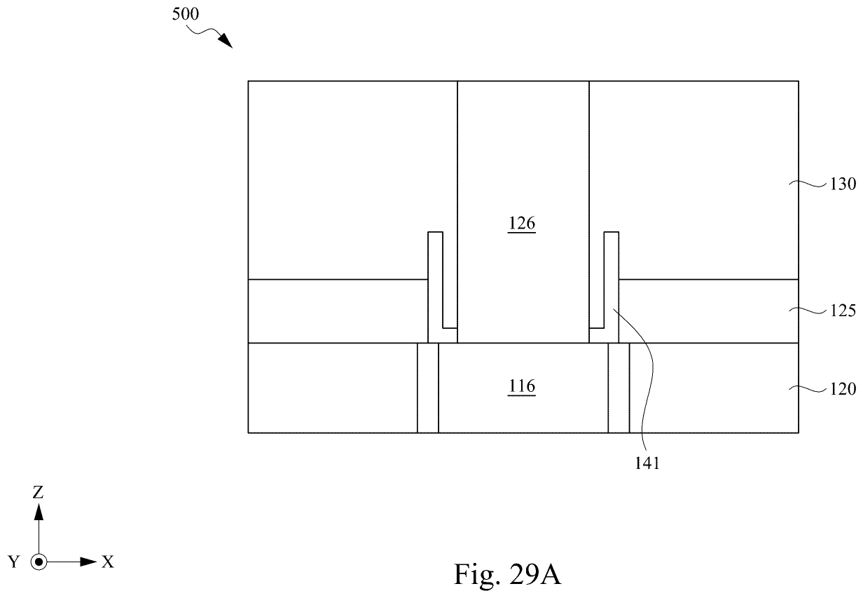

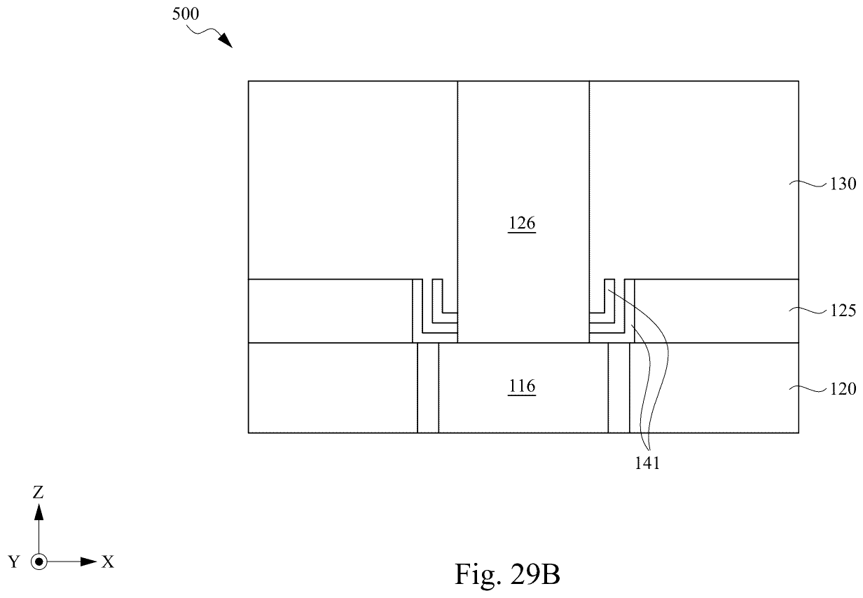

FIGS. 29A-29B illustrate metal vias or contacts (e.g., S/D via 126) isolated from etch stop layers (e.g., ESL 125), according to further embodiments of the present disclosure. Note that in the embodiments of FIG. 29A-29B, the device 100 is processed according to the second embodiment 1200b described in FIG. 10B.

Referring to FIG. 29A, operation 1118 may be tuned such that the sealed air gaps 141 have a height above or below the ESL. For example, implantation at a lower energy and/or dosage may only laterally expand a top portion of the second dielectric layer (e.g., ILD layer 130), while a bottom portion remain nonimplanted. As a result, only the top portion of the second dielectric layer (e.g., ILD layer 130) laterally expands to interface the protective liners 230. In this case, as shown in FIG. 29A, the sealed air gaps 141 have a greater height than the ESL. For another example, implantation at a higher energy and/or dosage may further push the already fully laterally expanded second dielectric layer (e.g., ILD layer 130) into bottom portions of the air gaps 141. In this case, the sealed air gaps 141 have a lower height than the ESL (not shown).

Referring to FIG. 29B, in further embodiments, multiple air gaps 141 may be formed between a metal via or contact (e.g., S/D via 126) and a ESL (e.g., ESL 125). For example, instead of forming a bi-layer structure of sacrificial liners 213 and protective liners 230, a quad-layer structure of alternating sacrificial liners 213, protective liners 230, sacrificial liners 213, and protective liners 230 is formed. And the two sacrificial liners 213 of the quad-layer are selectively removed, while the two protective liners 230 remain and become part of the second dielectric layer (e.g., ILD layer 130) after ion implantation. In these embodiments, greater reduction to parasitic capacitance may be achieved. Although not shown, like in the embodiment of FIG. 20A, the multiple air gaps 141 may also have heights above or below the ESL.

Although not limiting, the present disclosure offers advantages for forming metal contacts/vias. One example advantage is forming air gaps laterally between metal contacts/vias and etch stop layers to reduce stray capacitive coupling. Another example advantage is forming protective liners that assist in bottom-up metal growth. Another example advantage is sealing air gaps through ion implantation to prepare for further processing. Another example advantage is forming multiple air gaps and/or air gaps at different heights according to design requirements.

One aspect of the present disclosure pertains to a structure. The structure includes a first interlayer dielectric (ILD) layer; a conductive feature disposed in the first ILD layer; an etch stop layer (ESL) disposed on the first ILD layer; a second ILD layer disposed on the ESL; and a metal feature disposed in the second ILD layer and in contact with the conductive feature, where the metal feature is laterally separated from the ESL by an air gap.

In an embodiment, the metal feature is further laterally separated from the ESL by a portion of the second ILD layer. In an embodiment, the portion of the second ILD layer lands on the conducive feature. In an embodiment, the portion of the second ILD layer is isolated from the conducive feature by a lateral portion of the air gap.

In an embodiment, the first and the second ILD layers include silicon oxide, wherein the second ILD layer further includes germanium, and a top portion of the second ILD layer has a greater concentration of germanium than a bottom portion of the second ILD layer. In an embodiment, the top portion of the second ILD layer seals the air gap.

In an embodiment, a top surface of the air gap is above a top surface of the etch stop layer. In an embodiment, the metal feature is further laterally separated from the ESL by a second air gap embedded in the second ILD layer.

In an embodiment, the ESL is a low-k dielectric. In an embodiment, the ESL includes silicon nitride. In a further embodiment, the ESL further includes carbon.

Another aspect of the present disclosure pertains to a structure. The structure includes a source/drain (S/D) contact over an S/D feature; a gate structure over a channel region, wherein the channel region is adjacent the S/D feature; a first interlayer dielectric (ILD) layer over the gate structure and surrounding the S/D contact; an etch stop layer over the first ILD layer and the S/D contact; a second ILD layer over the etch stop layer; and an S/D via landing on the S/D contact, wherein the S/D via is embedded in the second ILD layer and separated from the etch stop layer.

In an embodiment, a portion of the second ILD layer is laterally between the S/D via and the etch stop layer. In an embodiment, the S/D via is isolated from the etch stop layer by an air gap, wherein the air gap is disposed laterally between the S/D via and the etch stop layer. In an embodiment, the first and second ILD layer includes an oxide-based dielectric and the etch stop layer includes a nitride-based dielectric. In an embodiment, the etch stop layer includes silicon carbonitride. In an embodiment, the second ILD layer has a bottom portion that dips below a top surface of the etch stop layer.

Another aspect of the present disclosure pertains to a method. The method includes forming a metal contact in a first dielectric layer; depositing an etch stop layer (ESL) over the metal contact and the first dielectric layer; depositing a second dielectric layer over the ESL; form a trench through the second dielectric layer and the ESL to expose the metal contact; form sacrificial liners along sidewalls of the trench; form protective liners along sidewalls of the sacrificial liners; deposit a metal in the trench and between the protective liners; selectively remove the sacrificial liners to form air gaps; and seal the air gaps by performing ion implantation to the second dielectric layer.

In an embodiment, the sacrificial liners and the protective liners include different materials.

In an embodiment, the protective liners and the second dielectric layer include a same dielectric material.

The details of the method and system of the present disclosure are described in the attached drawings. The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A structure comprising:
a first interlayer dielectric (ILD) layer;
a conductive feature disposed in the first ILD layer;
an etch stop layer (ESL) disposed on the first ILD layer;
a second ILD layer disposed on the ESL; and
a metal feature disposed in the second ILD layer and in contact with the conductive feature, wherein the metal feature is laterally separated from the ESL by an air gap.

2. The structure of claim 1, wherein the metal feature is further laterally separated from the ESL by a portion of the second ILD layer.

3. The structure of claim 2, wherein the portion of the second ILD layer lands on the conducive feature.

4. The structure of claim 2, wherein the portion of the second ILD layer is isolated from the conducive feature by a lateral portion of the air gap.

5. The structure of claim 1, wherein the first and the second ILD layers include silicon oxide, wherein the second ILD layer further includes germanium, and a top portion of the second ILD layer has a greater concentration of germanium than a bottom portion of the second ILD layer.

6. The structure of claim 5, wherein the top portion of the second ILD layer seals the air gap.

7. The structure of claim 1, wherein a top surface of the air gap is above a top surface of the etch stop layer.

8. The structure of claim 1, wherein the metal feature is further laterally separated from the ESL by a second air gap embedded in the second ILD layer.

9. The structure of claim 1, wherein the ESL is a low-k dielectric.

10. The structure of claim 1, wherein the ESL includes silicon nitride.

11. The structure of claim 9, wherein the ESL further includes carbon.

12. A structure comprising:
a source/drain (S/D) contact over an S/D feature;
a gate structure over a channel region, wherein the channel region is adjacent the S/D feature;
a first interlayer dielectric (ILD) layer over the gate structure and surrounding the S/D contact;
an etch stop layer over the first ILD layer and the S/D contact;
a second ILD layer over the etch stop layer; and
an S/D via landing on the S/D contact, wherein the S/D via is embedded in the second ILD layer and separated from the etch stop layer.

13. The structure of claim 12, wherein a portion of the second ILD layer is laterally between the S/D via and the etch stop layer.

14. The structure of claim 12, wherein the S/D via is isolated from the etch stop layer by an air gap, wherein the air gap is disposed laterally between the S/D via and the etch stop layer.

15. The structure of claim 12, wherein the first and second ILD layer includes an oxide-based dielectric and the etch stop layer includes a nitride-based dielectric.

16. The structure of claim 12, wherein the etch stop layer includes silicon carbonitride.

17. The structure of claim 12, wherein the second ILD layer has a bottom portion that dips below a top surface of the etch stop layer.

18. A method, comprising:
forming a metal contact in a first dielectric layer;
depositing an etch stop layer (ESL) over the metal contact and the first dielectric layer;
depositing a second dielectric layer over the ESL;
form a trench through the second dielectric layer and the ESL to expose the metal contact;
form sacrificial liners along sidewalls of the trench;
form protective liners along sidewalls of the sacrificial liners;
deposit a metal in the trench and between the protective liners;
selectively remove the sacrificial liners to form air gaps; and
seal the air gaps by performing ion implantation to the second dielectric layer.

19. The method of claim 18, wherein the sacrificial liners and the protective liners include different materials.

20. The method of claim 18, wherein the protective liners and the second dielectric layer include a same dielectric material.
